(19) United States
(12) Patent Application Publication
(10) Pub. No.: US 2025/0264556 A1
(43) Pub. Date: Aug. 21, 2025

(54) MAGNETORESISTIVE EFFECT ELEMENT, MAGNETIC FIELD DETECTION DEVICE, AND MAGNETIC SENSOR SYSTEM

(71) Applicant: TDK Corporation, Tokyo (JP)

(72) Inventor: Takafumi KOBAYASHI, Tokyo (JP)

(73) Assignee: TDK Corporation, Tokyo (JP)

(21) Appl. No.: 18/947,252

(22) Filed: Nov. 14, 2024

(30) Foreign Application Priority Data
Feb. 20, 2024 (JP) 2024-023438

(51) Int. Cl. G01R 33/09

(52) U.S. Cl. CPC G01R 33/098; G01R 33/093

(57) ABSTRACT

A magnetoresistive effect element includes a stacked structure including a first magnetization free layer, a first nonmagnetic layer, and a second magnetization free layer that are stacked in order in a stacking direction. An outer edge of the stacked structure along a plane orthogonal to the stacking direction has an isotropic shape.

### CROSS-REFERENCE TO RELATED APPLICATIONS

The present application claims priority from Japanese Patent Application No. 2024-023438 filed on Feb. 20, 2024, the entire contents of which are hereby incorporated by reference.

### BACKGROUND

The disclosure relates to a magnetoresistive effect element, and to a magnetic field detection device and a magnetic sensor system that each include the magnetoresistive effect element.

A magnetic sensor including a magnetoresistive effect element has been used in various applications. The magnetoresistive effect element includes, for example, a magnetization pinned layer having a magnetization pinned in a certain direction, a magnetization free layer having a magnetization whose direction is changeable in accordance with a direction of an applied magnetic field, and a nonmagnetic layer disposed between the magnetization pinned layer and the magnetization free layer.

Further, for example, Japanese Unexamined Patent Application Publication (JP-A) No. 2023-055294 proposes a magnetoresistive effect element including a first magnetic layer, a nonmagnetic layer, and a second magnetic layer arranged in order. The first magnetic layer has a magnetic shape anisotropy set in a first reference direction and has a magnetization whose direction changes in accordance with an external magnetic field. The second magnetic layer has a magnetic shape anisotropy set in a second reference direction intersecting the first reference direction and has a magnetization whose direction changes in accordance with the external magnetic field. JP-A No. 2023-055294 further discloses a magnetic sensor that detects an intensity and a direction of the external magnetic field, based on a change in resistance value of the magnetoresistive effect element in response to a change in the external magnetic field.

International Publication No. WO 2020/250489 proposes a magnetic sensor including a magnetic field intensity sensor and a magnetic field angle sensor.

### SUMMARY

A magnetoresistive effect element according to one embodiment of the disclosure includes a stacked structure including a first magnetization free layer, a first nonmagnetic layer, and a second magnetization free layer that are stacked in order in a stacking direction. An outer edge of the stacked structure along a plane orthogonal to the stacking direction has an isotropic shape.

A magnetic field detection device according to one embodiment of the disclosure includes one or more magnetoresistive effect elements. The one or more magnetoresistive effect elements each include a stacked structure including a first magnetization free layer, a first nonmagnetic layer, and a second magnetization free layer that are stacked in order in a stacking direction. An outer edge of the stacked structure along a plane orthogonal to the stacking direction has an isotropic shape.

A magnetic field detection device according to one embodiment of the disclosure includes a bridge circuit including first to fourth magnetoresistive effect elements. The first to fourth magnetoresistive effect elements each include a stacked structure including a magnetization pinned layer, a second nonmagnetic layer, a second magnetization free layer, a first nonmagnetic layer, and a first magnetization free layer that are stacked in order in a stacking direction. The first magnetization free layer has an easy axis of magnetization along the stacking direction. The second magnetization free layer has a hard axis of magnetization along the stacking direction.

A magnetic sensor system according to one embodiment of the disclosure includes a magnetic field detection device, and a magnetic field generator generating a magnetic field. The magnetic sensor system is configured to change a direction of the magnetic field applied to the magnetic field detection device, by causing the magnetic field detection device and the magnetic field generator to rotate relative to each other around a first axis as a center of rotation, and configured to change an intensity of the magnetic field applied to the magnetic field detection device, by changing relative positions of the magnetic field detection device and the magnetic field generator along the first axis. The magnetic field detection device includes one or more magnetoresistive effect elements. The one or more magnetoresistive effect elements each include a stacked structure including a first magnetization free layer, a first nonmagnetic layer, and a second magnetization free layer that are stacked in order in a stacking direction. An outer edge of the stacked structure along a plane orthogonal to the stacking direction has an isotropic shape.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the disclosure.

FIG. 1A is a perspective diagram illustrating an outer appearance of a magnetoresistive effect element according to one example embodiment of the disclosure.

FIG. 1B is a cross-sectional diagram illustrating a cross-sectional configuration of the magnetoresistive effect element illustrated in FIG. 1A.

FIG. 2 is a characteristic diagram illustrating a relationship between a magnetic flux density of an external magnetic field applied to the magnetoresistive effect element illustrated in FIG. 1A and a resistance value of the magnetoresistive effect element.

FIGS. 3A to 3F are explanatory diagrams that schematically describe a relationship between a magnitude of the magnetic flux density of the external magnetic field applied to the magnetoresistive effect element illustrated in FIG. 1A and directions of magnetizations.

FIG. 4 is a cross-sectional diagram illustrating a cross-sectional configuration of a magnetoresistive effect element according to a first modification example of the example embodiment illustrated in FIG. 1A.

FIG. 5 is a characteristic diagram illustrating a relationship between the magnetic flux density of an external magnetic field applied to the magnetoresistive effect element illustrated in FIG. 4 and the resistance value of the magnetoresistive effect element.

FIGS. 6A to 6F are explanatory diagrams that schematically describe a relationship between the magnitude of the magnetic flux density of the external magnetic field applied to the magnetoresistive effect element illustrated in FIG. 4 and the directions of the magnetizations.

FIG. 7 is a cross-sectional diagram illustrating a cross-sectional configuration of a magnetoresistive effect element according to a second modification example of the example embodiment illustrated in FIG. 1A.

FIG. 8 is a perspective diagram illustrating an outer appearance of a magnetoresistive effect element according to a third modification example of the example embodiment illustrated in FIG. 1A.

FIG. 9 is a characteristic diagram illustrating a relationship between the magnetic flux density of an external magnetic field applied to the magnetoresistive effect element illustrated in FIG. 8 and the resistance value of the magnetoresistive effect element.

FIGS. 10A to 10E are explanatory diagrams that schematically describe a relationship between the magnitude of the magnetic flux density of the external magnetic field applied to the magnetoresistive effect element illustrated in FIG. 8 and the direction of a magnetization.

FIG. 11 is a cross-sectional diagram illustrating a cross-sectional configuration of a magnetoresistive effect element according to a fourth modification example of the example embodiment illustrated in FIG. 1A.

FIG. 12 is a characteristic diagram illustrating a relationship between the magnetic flux density of an external magnetic field applied to the magnetoresistive effect element illustrated in FIG. 11 and the resistance value of the magnetoresistive effect element.

FIGS. 13A to 13E are explanatory diagrams that schematically describe a relationship between the magnitude of the magnetic flux density of the external magnetic field applied to the magnetoresistive effect element illustrated in FIG. 11 and the directions of the magnetizations.

FIG. 14 is a circuit diagram schematically illustrating a circuit configuration of a magnetic field detection device according to one example embodiment of the disclosure.

FIG. 15 is a characteristic diagram schematically illustrating a relationship between a differential output outputted from a bridge circuit of the magnetic field detection device illustrated in FIG. 14 and an intensity of the external magnetic field.

FIG. 16 is a circuit diagram schematically illustrating a circuit configuration of a magnetic field detection device according to one example embodiment of the disclosure.

FIG. 17 is a circuit diagram schematically illustrating a circuit configuration of a magnetic field detection device according to one example embodiment of the disclosure.

FIG. 18 is a perspective diagram schematically illustrating a magnetic sensor system according to one example embodiment of the disclosure.

### DETAILED DESCRIPTION

It is desired that a magnetic field detection device including a magnetoresistive effect element be more simple in configuration from a viewpoint of manufacturability or cost savings.

It is desirable to provide a magnetic field detection device and a magnetic sensor system that are each simple in configuration and yet make it possible to isotropically detect an intensity of an external magnetic field without dependence on a direction of the external magnetic field, and to provide a magnetoresistive effect element for use in such a magnetic field detection device or magnetic sensor system.

In the following, some example embodiments of the disclosure are described in detail with reference to the accompanying drawings. Note that the following description is directed to illustrative examples of the disclosure and not to be construed as limiting to the disclosure. Factors including, without limitation, numerical values, shapes, materials, components, positions of the components, and how the components are coupled to each other are illustrative only and not to be construed as limiting to the disclosure. Further, elements in the following example embodiments which are not recited in a most-generic independent claim of the disclosure are optional and may be provided on an as-needed basis. The drawings are schematic and are not intended to be drawn to scale. Throughout the present specification and the drawings, elements having substantially the same function and configuration are denoted with the same reference numerals to avoid any redundant description. In addition, elements that are not directly related to any embodiment of the disclosure are unillustrated in the drawings. Note that the description is given in the following order.
0. Background
1. First Example Embodiment and Modification Examples thereof
   Examples of a magnetoresistive effect element including two magnetization free layers.
2. Second Example Embodiment
   An example of a first magnetic field detection device with a circuit including a magnetoresistive effect element.
3. Third Example Embodiment
   An example of a second magnetic field detection device with a circuit including a magnetoresistive effect element.
3. Fourth Example Embodiment
   An example of a third magnetic field detection device with a circuit including a magnetoresistive effect element.
4. Fifth Example Embodiment
   An example of an application including the magnetic field detection device.

### 0. Background

A magnetic field angle sensor to detect a direction of an external magnetic field has been widely used. Such a magnetic field angle sensor includes, for example, a magnetoresistive effect element in which a magnetization free layer and a magnetization pinned layer are stacked with a nonmagnetic layer interposed therebetween. The magnetization free layer has a magnetization whose direction rotates in accordance with the direction of the external magnetic field. The magnetization pinned layer has a magnetization whose direction remains unchanged irrespective of the external magnetic field. The magnetic field angle sensor acquires angle data on the external magnetic field, based on a change in resistance value of the magnetoresistive effect element that depends on a relative angle between respective magnetization directions of the magnetization free layer and the magnetization pinned layer.

However, intensity data on the external magnetic field is difficult to acquire with the magnetic field angle sensor. To detect the intensity of the external magnetic field, it is thus necessary to separately provide a magnetic field intensity sensor including a magnetoresistive effect element or any other suitable element. In a case of the magnetoresistive effect element including the magnetization pinned layer, it is necessary that the relative angle between the respective magnetization directions of the magnetization free layer and the magnetization pinned layer be caused to change in accordance with the intensity of the external magnetic field in an in-plane direction in a stack plane orthogonal to a stacking direction; however, an effective magnetic field component, on the magnetization free layer, contributing to the above-described relative angle varies depending on the direction of the external magnetic field. It is therefore difficult to acquire intensity data for all of the in-plane directions in the stack plane.

To address this, JP-A No. 2023-055294 proposes a magnetoresistive effect element without any magnetization pinned layer. However, the magnetoresistive effect element disclosed in JP-A No. 2023-055294 includes two magnetization free layers having their respective magnetic shape anisotropies in different directions from each other. Accordingly, there is room for improvement in that, in JP-A No. 2023-055294, the two magnetization free layers are to be formed separately.

In view of the above-described circumstances, the Applicant provides a magnetoresistive effect element, a magnetic field sensor, and a magnetic sensor system that each have a simple configuration superior in manufacturability and yet help to isotropically detect the intensity of the external magnetic field without dependence on the direction of the external magnetic field.

### 1. First Example Embodiment

### [Configuration of Magnetoresistive Effect Element 10]

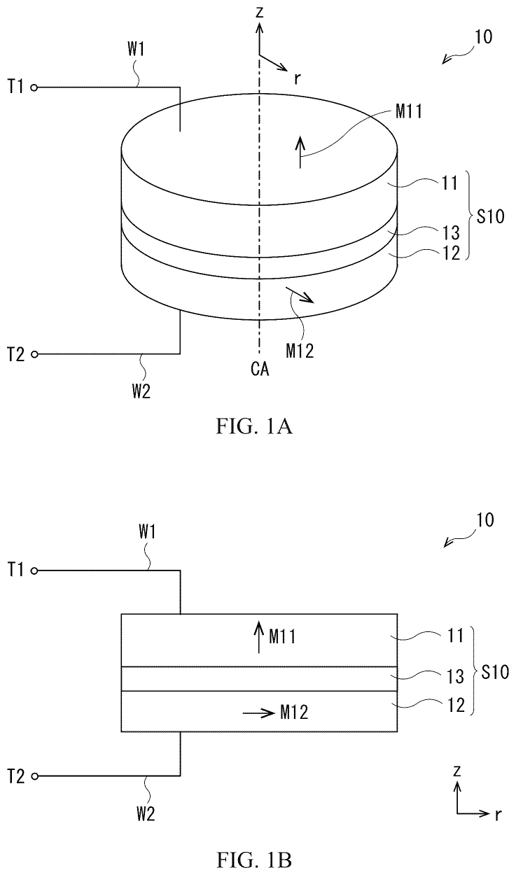

A description will be given first of a configuration of a magnetoresistive effect element 10 according to a first example embodiment of the disclosure with reference to FIGS. 1A and 1B. FIG. 1A is a perspective diagram illustrating a visual configuration example of the magnetoresistive effect element 10. FIG. 1B is a cross-sectional diagram illustrating a cross-sectional configuration example of the magnetoresistive effect element 10. The magnetoresistive effect element 10 may correspond to a specific but non-limiting example of a “magnetoresistive effect element” in one embodiment of the disclosure.

As illustrated in FIG. 1A, the magnetoresistive effect element 10 includes a stacked structure S10. The stacked structure S10 may have an external appearance of a substantially circular columnar shape with a central axis CA. A direction of a height of the magnetoresistive effect element 10 along the central axis CA is defined herein as a z direction. A direction of a radius, of the magnetoresistive effect element 10 having the substantially circular columnar shape, orthogonal to the z direction is defined herein as an r direction. FIG. 1B thus illustrates the cross-sectional configuration example along the z direction. Note that the r direction refers to any of in-plane directions orthogonal to the z direction, and does not refer to a specific one of such directions.

The magnetoresistive effect element 10 includes the stacked structure S10 including, for example, a first magnetization free layer 11, a nonmagnetic layer 13, and a second magnetization free layer 12 that are stacked in order along the z direction as a stacking direction. An outer edge of the stacked structure S10 along a stack plane, i.e., a plane orthogonal to the z direction, has an isotropic shape. For example, the outer edge of the stacked structure S10 along the stack plane orthogonal to the z direction may have a circular shape. As used herein, the term “circular shape” is not limited to a geometrically exact circular shape, that is, a perfect circular shape, and conceptually encompasses a circular shape with an error that is difficult to avoid, such as a manufacturing error or a measurement error. For example, a portion of a circumference of the circular shape may include a slight imperfection such as a slight chip, depression, or protrusion. Further, the “circular shape” herein may be slightly elongated, in which case, for example, a ratio of a minimum diameter to a maximum diameter may be higher than or equal to 0.9 and less than or equal to 1.0. Moreover, as used herein, the term “isotropic shape” is not limited to a circular shape, and conceptually encompasses a regular polygonal shape. Non-limiting examples of the regular polygonal shape may include a regular hexagonal shape and a regular octagonal shape. The “regular polygonal shape” herein is not limited to a geometrically exact regular polygonal shape, and conceptually encompasses a regular polygonal shape with an error that is difficult to avoid, such as a manufacturing error or a measurement error. For example, a portion of an outer edge of the regular polygonal shape may include a slight imperfection such as a slight chip, depression, or protrusion. Further, sides constituting the regular polygonal shape may differ in length from each other by about 10%.

The first magnetization free layer 11 may have a magnetization M11 that changes direction in accordance with an external magnetic field. The first magnetization free layer 11 may have an easy axis of magnetization along the z direction, for example. In other words, a magnetization stabilizing direction of the first magnetization free layer 11 may be parallel to the z direction. Accordingly, in an initial state where no external magnetic field is applied, the magnetization M11 may be oriented in a direction closer to the z direction than to the r direction.

The second magnetization free layer 12 may have a magnetization M12 that changes direction in accordance with the external magnetic field. The second magnetization free layer 12 may have a hard axis of magnetization along the z direction, for example. In other words, a magnetization stabilizing direction of the second magnetization free layer 12 may be any of the in-plane directions in the stack plane orthogonal to the z direction. Accordingly, in an initial state where no external magnetic field is applied, the magnetization M12 may be oriented in a direction closer to the r direction than to the z direction.

The first magnetization free layer 11 and the second magnetization free layer 12 may each be a soft ferromagnetic layer, and may include a material such as CoFe, NiFe, or CoFeB. The material included in the first magnetization free layer 11 and the material included in the second magnetization free layer 12 may be the same or different from each other in kind. Further, an anisotropic magnetic field intensity of the first magnetization free layer 11 and an anisotropic magnetic field intensity of the second magnetization free layer 12 may be different from each other.

When the stacked structure S10 has a magnetic tunnel junction (MTJ) structure, the nonmagnetic layer 13 may be a nonmagnetic tunnel barrier layer including, for example, a metal oxide such as magnesium oxide (MgO). When the nonmagnetic layer 13 is the tunnel barrier layer, the nonmagnetic layer 13 may be thin to the extent that a tunnel current based on quantum mechanics is allowed to pass through. In some embodiments, the nonmagnetic layer 13 may be a nonmagnetic electrically-conductive layer including a nonmagnetic metal such as a platinum group element or copper (Cu). Non-limiting examples of the platinum group element may include ruthenium (Ru) and gold (Au). In such a case, the stacked structure S10 may be a giant magnetoresistive effect (GMR) film.

The magnetoresistive effect element 10 may be of a current-perpendicular-to-plane (CPP) type that allows a current for signal detection to flow in a direction substantially perpendicular to the stack plane in which the first magnetization free layer 11, the nonmagnetic layer 13, and the second magnetization free layer 12 each extend. When the current flows in the z direction through the magnetoresistive effect element 10 in a state where an external magnetic field is applied thereto, the magnetoresistive effect element 10 exhibits a resistance value corresponding to the external magnetic field. When the external magnetic field applied to the magnetoresistive effect element 10 changes, the resistance value of the magnetoresistive effect element 10 also changes.

A first coupling terminal T1 may be coupled to the first magnetization free layer 11 via a wiring W1. A second coupling terminal T2 may be coupled to the second magnetization free layer 12 via a wiring W2. Applying a voltage between the first coupling terminal T1 and the second coupling terminal T2 causes a current to flow through the magnetoresistive effect element 10 in the z direction.

### [Behavior of Magnetoresistive Effect Element 10]

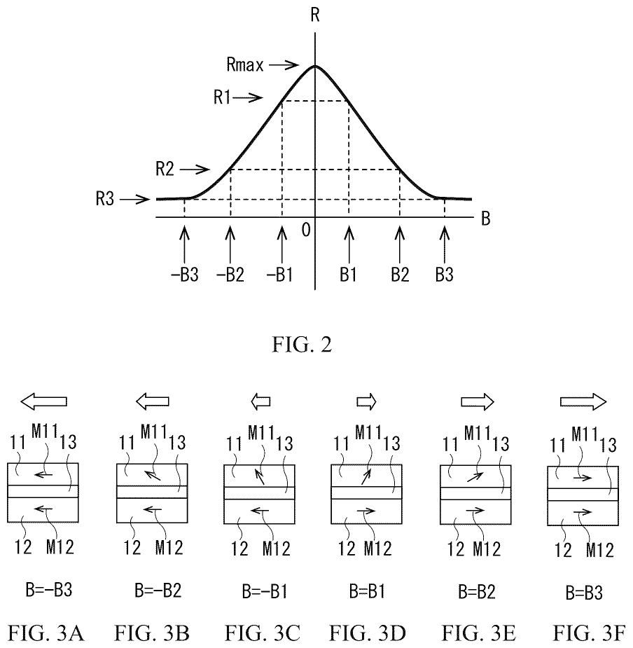

Reference is now made to FIG. 2 and FIGS. 3A to 3F to describe a behavior of the magnetoresistive effect element 10. FIG. 2 is a characteristic diagram illustrating a relationship between a magnetic flux density B of an external magnetic field applied to the magnetoresistive effect element 10 and a resistance value R of the magnetoresistive effect element 10 when a current is fed through the magnetoresistive effect element 10 in the z direction. In FIG. 2, the horizontal axis represents the magnetic flux density B, and the vertical axis represents the resistance value R FIGS. 3A to 3F are explanatory diagrams schematically illustrating the behavior of the magnetoresistive effect element 10 when the external magnetic field is applied, in other words, how the magnetizations M11 and M12 change in accordance with a magnitude of the magnetic flux density B of the external magnetic field applied to the magnetoresistive effect element 10.

FIG. 3A illustrates directions of the magnetizations M11 and M12 when the magnetic flux density B is equal to −B3 in the characteristic diagram of FIG. 2. FIG. 3B illustrates the directions of the magnetizations M11 and M12 when the magnetic flux density B is equal to −B2 in the characteristic diagram of FIG. 2. FIG. 3C illustrates the directions of the magnetizations M11 and M12 when the magnetic flux density B is equal to −B1 in the characteristic diagram of FIG. 2. FIG. 3D illustrates the directions of the magnetizations M11 and M12 when the magnetic flux density B is equal to B1 in the characteristic diagram of FIG. 2. FIG. 3E illustrates the directions of the magnetizations M11 and M12 when the magnetic flux density B is equal to B2 in the characteristic diagram of FIG. 2. FIG. 3F illustrates the directions of the magnetizations M11 and M12 when the magnetic flux density B is equal to B3 in the characteristic diagram of FIG. 2. Note that B1 and −B1 are equal in absolute value, B2 and −B2 are equal in absolute value, and B3 and −B3 are equal in absolute value. A length and a direction of a hollow arrow illustrated in each of FIGS. 3A to 3F represent an intensity and a direction, respectively, of the external magnetic field applied to the magnetoresistive effect element 10. For example, the hollow arrow having a greater length indicates that the external magnetic field has a greater intensity. Further, FIGS. 3A to 3C indicate that the external magnetic field is applied to the magnetoresistive effect element 10 in a leftward direction in the sheet plane, and FIGS. 3D to 3F indicate that the external magnetic field is applied to the magnetoresistive effect element 10 in a rightward direction in the sheet plane. Note that the directions of the magnetizations M11 and M12 when the magnetic flux density B is zero (0) in the characteristic diagram of FIG. 2 are as illustrated in FIG. 1B.

As indicated in FIGS. 2 and 3A to 3F, the direction of the magnetization M11 of the first magnetization free layer 11 changes in accordance with the magnitude of the magnetic flux density B. In contrast, the second magnetization free layer 12 easily becomes magnetically saturated by application of the external magnetic field, and the direction of the magnetization M12 of the second magnetization free layer 12 approaches the direction in which the external magnetic field is applied, irrespective of the magnitude of the magnetic flux density B. Further, the resistance value R of the magnetoresistive effect element 10 reaches a maximum resistance value Rmax when the magnetic flux density B is zero. One reason for this is that when the magnetic flux density B is zero, the direction of the magnetization M11 of the first magnetization free layer 11 is in a state of being substantially parallel to the z direction, which causes an angle between the direction of the magnetization M11 and the direction of the magnetization M12 that is stable in a +r direction or a −r direction orthogonal to the z direction to become maximum, i.e., 90°.

As the absolute value of the magnetic flux density B increases from zero, the resistance value R of the magnetoresistive effect element 10 gradually decreases and approaches a constant value (R=R3). For example, a resistance value R1 lower than the maximum resistance value Rmax, a resistance value R2 lower than the resistance value R1, and the resistance value R3 lower than the resistance value R2 will result. One reason for this is that as the magnetic flux density B increases, the direction of the magnetization M11 of the first magnetization free layer 11 gradually tilts from the state of being substantially parallel to the z direction and approaches being parallel to the +r direction or the −r direction.

### Example Effects of Magnetoresistive Effect Element 10

In this way, the magnetoresistive effect element 10 exhibits a change in resistance value corresponding to the intensity (i.e., the magnetic flux density) of the external magnetic field applied to the magnetoresistive effect element 10. Therefore, understanding a correlation between the intensity (i.e., the magnetic flux density) of the external magnetic field and the resistance value of the magnetoresistive effect element 10 in advance helps to calculate the intensity of the external magnetic field through detection of the change in the resistance value. In the magnetoresistive effect element 10, the outer edge of the stacked structure S10 along the stack plane orthogonal to the z direction may have a circular shape. This helps to isotropically detect the intensity of the external magnetic field without dependence on the direction of the external magnetic field.

### Modification Examples of First Example Embodiment

### First Modification Example

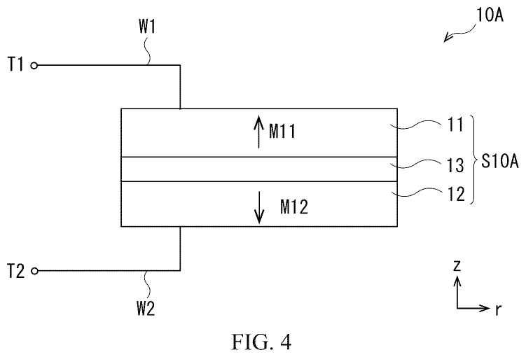

FIG. 4 is a cross-sectional diagram illustrating a cross-sectional configuration example of a magnetoresistive effect element 10A according to a first modification example (hereinafter, “Modification Example 1-1”) of the first example embodiment of the disclosure. FIG. 4 corresponds to FIG. 1B illustrating the magnetoresistive effect element 10 according to the foregoing first example embodiment. In the stacked structure S10 of the magnetoresistive effect element 10 according to the foregoing first example embodiment, the direction of the magnetization M11 of the first magnetization free layer 11 in the initial state may be substantially parallel to the z direction, and the direction of the magnetization M12 of the second magnetization free layer 12 in the initial state may be substantially parallel to the r direction. In contrast, in a stacked structure S10A of the magnetoresistive effect element 10A according to Modification Example 1-1, the direction of the magnetization M12 of the second magnetization free layer 12 in the initial state may be substantially parallel to the z direction. In the stacked structure S10A of the magnetoresistive effect element 10A, both the first magnetization free layer 11 and the second magnetization free layer 12 may thus have the easy axis of magnetization along the z direction. However, the direction of the magnetization M11 in the initial state may be substantially parallel to a +z direction, and the direction of the magnetization M12 in the initial state may be substantially parallel to a −z direction. In other words, in the magnetoresistive effect element 10A, the direction of the magnetization M11 and the direction of the magnetization M12 may be nearly antiparallel to each other in the initial state. The magnetoresistive effect element 10A may be otherwise substantially the same in configuration as the magnetoresistive effect element 10.

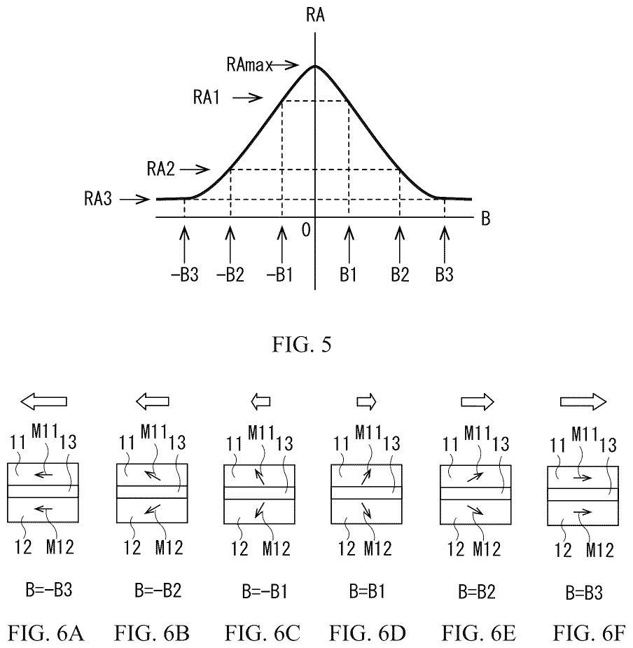

FIG. 5 is a characteristic diagram illustrating a relationship between the magnetic flux density B of an external magnetic field applied to the magnetoresistive effect element 10A and a resistance value RA of the magnetoresistive effect element 10A when a current is fed through the magnetoresistive effect element 10A in the z direction. In FIG. 5, the horizontal axis represents the magnetic flux density B, and the vertical axis represents the resistance value RA. FIGS. 6A to 6F are explanatory diagrams schematically illustrating the behavior of the magnetoresistive effect element 10A when the external magnetic field is applied, in other words, how the magnetizations M11 and M12 change in accordance with the magnitude of the magnetic flux density B of the external magnetic field applied to the magnetoresistive effect element 10A. FIG. 5 corresponds to FIG. 2 illustrating the characteristic diagram of the magnetoresistive effect element 10 of the foregoing first example embodiment. FIGS. 6A to 6F correspond to FIGS. 3A to 3F illustrating the explanatory diagrams of the magnetoresistive effect element 10 of the foregoing first example embodiment.

As illustrated in FIGS. 5 and 6A to 6F, the magnetoresistive effect element 10A exhibits a behavior similar to that of the magnetoresistive effect element 10 of the foregoing first example embodiment in response to the external magnetic field applied to the magnetoresistive effect element 10A. For example, the resistance value RA of the magnetoresistive effect element 10A reaches a maximum resistance value RAmax when the magnetic flux density B is zero. Note that the maximum resistance value RAmax of the magnetoresistive effect element 10A is larger than the maximum resistance value Rmax of the magnetoresistive effect element 10. One reason for this is that when the magnetic flux density B is zero, the direction of the magnetization M11 of the first magnetization free layer 11 is in a state of being substantially parallel to the +z direction and the direction of the magnetization M12 of the second magnetization free layer 11 is in a state of being substantially parallel to the −z direction, which causes the angle between the direction of the magnetization M11 and the direction of the magnetization M12 to be substantially 180°.

As the absolute value of the magnetic flux density B increases from zero, the resistance value RA of the magnetoresistive effect element 10A gradually decreases and approaches a constant value (RA=RA3). For example, a resistance value RA1 lower than the maximum resistance value RAmax, a resistance value RA2 lower than the resistance value RA1, and the resistance value RA3 lower than the resistance value RA2 will result. One reason for this is that as the magnetic flux density B increases, the direction of the magnetization M11 of the first magnetization free layer 11 gradually tilts from the state of being substantially parallel to the z direction and approaches being parallel to the +r direction or the −r direction.

In this way, the magnetoresistive effect element 10A also exhibits a change in resistance value corresponding to the intensity (i.e., the magnetic flux density) of the external magnetic field applied to the magnetoresistive effect element 10A. Therefore, understanding a correlation between the intensity (i.e., the magnetic flux density) of the external magnetic field and the resistance value of the magnetoresistive effect element 10A in advance helps to calculate the intensity of the external magnetic field through detection of the change in the resistance value.

### Second Modification Example

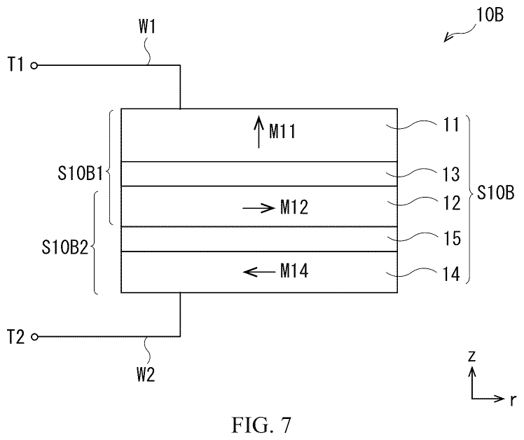

FIG. 7 is a cross-sectional diagram illustrating a cross-sectional configuration example of a magnetoresistive effect element 10B according to a second modification example (hereinafter, “Modification Example 1-2”) of the first example embodiment of the disclosure. FIG. 7 corresponds to FIG. 1B illustrating the magnetoresistive effect element 10 according to the foregoing first example embodiment. The magnetoresistive effect element 10B according to Modification Example 1-2 may include a stacked structure S10B instead of the stacked structure S10. The magnetoresistive effect element 10B may be otherwise substantially the same in configuration as the magnetoresistive effect element 10 according to the foregoing first example embodiment. The stacked structure S10B may include, in addition to the components of the stacked structure S10, a nonmagnetic layer 15 and a magnetization pinned layer 14 stacked in order on a side, of the second magnetization free layer 12, opposite to the nonmagnetic layer 13.

The nonmagnetic layer 15 may be a tunnel barrier layer or a nonmagnetic electrically-conductive layer, as with the nonmagnetic layer 13, for example. The nonmagnetic layer 15 may thus include a material the same as the material included in the nonmagnetic layer 13.

The nonmagnetic layer 15 may correspond to a specific but non-limiting example of a “second nonmagnetic layer” in one embodiment of the disclosure.

The magnetization pinned layer 14 may be a ferromagnetic layer having a magnetization that is pinned in a specific direction and does not change direction in accordance with an external magnetic field. In the example embodiment illustrated in FIG. 7, the magnetization pinned layer 14 may have a magnetization M14 pinned in the leftward direction in the sheet plane; however, the direction of the magnetization M14 is not limited to that illustrated in FIG. 7. The magnetization pinned layer 14 may include a ferromagnetic material such as cobalt (Co), cobalt-iron alloy (CoFe), or cobalt-iron-boron alloy (CoFeB). In the stacked structure S10B, an antiferromagnetic layer may be provided to be adjacent to the magnetization pinned layer 14 on an opposite side from the nonmagnetic layer 15. The antiferromagnetic layer includes an antiferromagnetic material. Non-limiting examples of the antiferromagnetic material may include platinum-manganese alloy (PtMn) and iridium-manganese alloy (IrMn).

The stacked structure S10B may correspond to a structure in which a magnetic field intensity data detector and a magnetic field angle data detector are stacked in the z direction. Accordingly, feeding a current through the stacked structure S10B in the z direction by applying a voltage between the coupling terminals T1 and T2 allows a change in resistance value corresponding to the intensity of the external magnetic field and a change in resistance value corresponding to the direction of the external magnetic field to be detected from the stacked structure S10B. For example, a stack part S10B1 including a stack of the first magnetization free layer 11, the nonmagnetic layer 13, and the second magnetization free layer 12 may serve as the magnetic field intensity data detector exhibiting a resistance value that changes in accordance with the intensity of the external magnetic field. A stack part S10B2 including a stack of the second magnetization free layer 12, the nonmagnetic layer 15, and the magnetization pinned layer 14 may serve as the magnetic field angle data detector exhibiting a resistance value that changes in accordance with the angle of the external magnetic field. When the direction of the external magnetic field rotates in any of the in-plane directions in the stack plane orthogonal to the z direction, the direction of the magnetization M12 of the second magnetization free layer 12 rotates to coincide with the direction of the external magnetic field. Accordingly, when the direction of the external magnetic field changes, an angle between the direction of the magnetization M12 and the direction of the magnetization M14 changes. The stack part S10B2 thus exhibits a resistance value corresponding to the direction of the external magnetic field.

In this way, in the magnetoresistive effect element 10B, the integrated stacked structure S10B helps to detect both intensity data and angle data on the external magnetic field.

### Third Modification Example

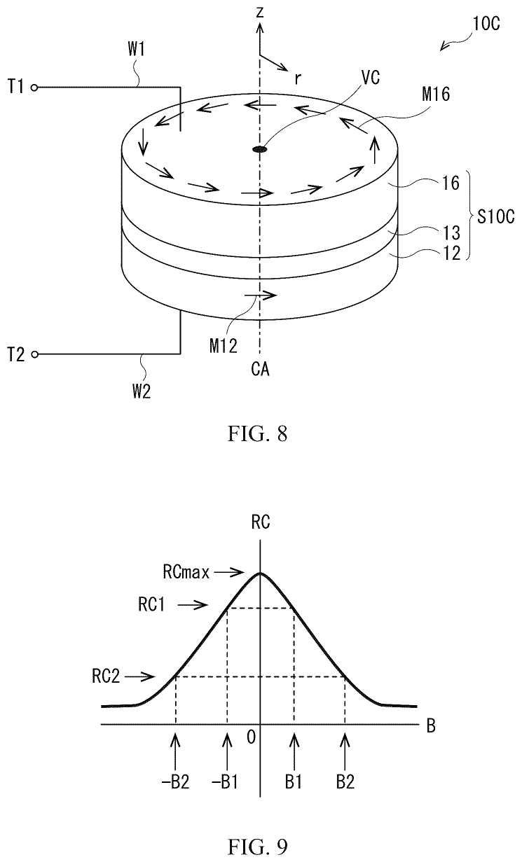

FIG. 8 is a perspective diagram illustrating an outer appearance of a magnetoresistive effect element 10C according to a third modification example (hereinafter, “Modification Example 1-3”) of the first example embodiment of the disclosure. FIG. 8 corresponds to FIG. 1A illustrating the magnetoresistive effect element 10 according to the foregoing first example embodiment. The magnetoresistive effect element 10C according to Modification Example 1-3 may include a stacked structure S10C instead of the stacked structure S10. The magnetoresistive effect element 10C may be otherwise substantially the same in configuration as the magnetoresistive effect element 10 according to the foregoing first example embodiment. The stacked structure S10C may include a first magnetization free layer 16 instead of the first magnetization free layer 11. The first magnetization free layer 16 may have what is called a spin-vortex structure. The first magnetization free layer 16 may include a magnetization M16 that spirals around a vortex core VC and along the stack plane orthogonal to the z direction.

FIG. 9 is a characteristic diagram illustrating a relationship between the magnetic flux density B of an external magnetic field applied to the magnetoresistive effect element 10C and a resistance value RC of the magnetoresistive effect element 10C when a current is fed through the magnetoresistive effect element 10C in the z direction. In FIG. 9, the horizontal axis represents the magnetic flux density B, and the vertical axis represents the resistance value RC. FIG. 9 corresponds to FIG. 2 illustrating the characteristic diagram of the magnetoresistive effect element 10 of the foregoing first example embodiment.

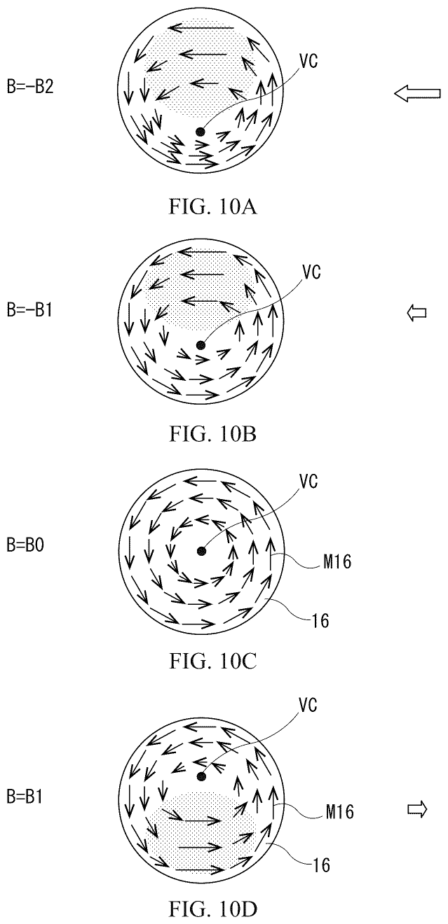

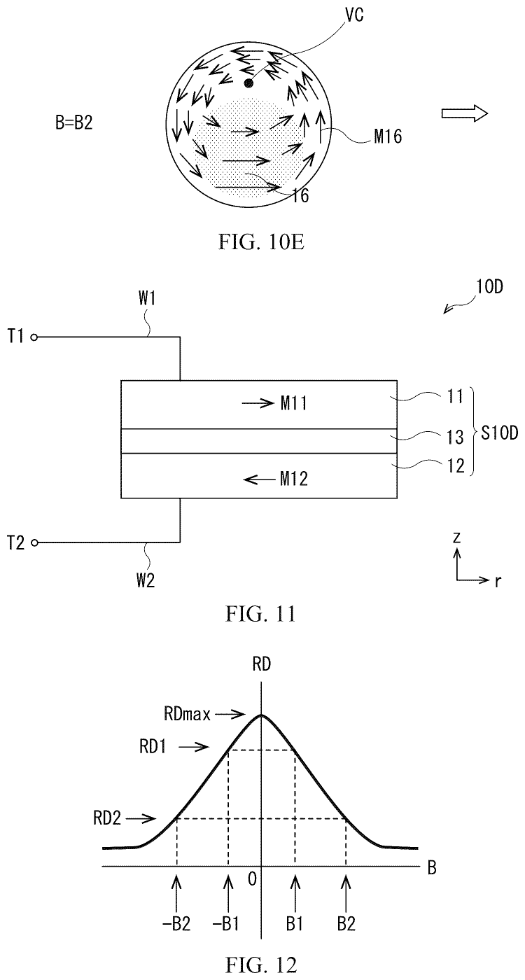

FIGS. 10A to 10E are explanatory diagrams schematically illustrating a behavior of the first magnetization free layer 16 of the magnetoresistive effect element 10C when the external magnetic field is applied, in other words, how the magnetization M16 changes in accordance with the magnitude of the magnetic flux density B of the external magnetic field applied to the magnetoresistive effect element 10C. FIG. 10A illustrates a direction of the magnetization M16 when the magnetic flux density B is equal to −B2 in the characteristic diagram of FIG. 9. FIG. 10B illustrates the direction of the magnetization M16 when the magnetic flux density B is equal to −B1 in the characteristic diagram of FIG. 9. FIG. 10C illustrates the direction of the magnetization M16 when the magnetic flux density B is zero (0) in the characteristic diagram of FIG. 9. FIG. 10D illustrates the direction of the magnetization M16 when the magnetic flux density B is equal to B1 in the characteristic diagram of FIG. 9. FIG. 10E illustrates the direction of the magnetization M16 when the magnetic flux density B is equal to B2 in the characteristic diagram of FIG. 9. Note that B1 and −B1 are equal in absolute value, and B2 and −B2 are equal in absolute value. The length and the direction of the hollow arrow illustrated in each of FIGS. 10A, 10B, 10D, and 10E represent the intensity and the direction, respectively, of the external magnetic field applied to the magnetoresistive effect element 10C. For example, the hollow arrow having a greater length indicates that the external magnetic field has a greater intensity. Further, FIGS. 10A and 10B indicate that the external magnetic field is applied to the magnetoresistive effect element 10C in the leftward direction in the sheet plane, and FIGS. 10D and 10E indicate that the external magnetic field is applied to the magnetoresistive effect element 10C in the rightward direction in the sheet plane.

As illustrated in FIG. 9, the magnetoresistive effect element 10C exhibits a behavior similar to that of the magnetoresistive effect element 10 of the foregoing first example embodiment in response to the external magnetic field applied to the magnetoresistive effect element 10C. For example, the resistance value RC of the magnetoresistive effect element 10C reaches a maximum resistance value RCmax when the magnetic flux density B is zero. FIGS. 8 and 10C schematically illustrate a state of the magnetoresistive effect element 10C when the magnetic flux density B is zero. As indicated in FIGS. 8 and 10C, when the magnetic flux density B of the external magnetic field is zero, the vortex core VC is present at a center of the stack plane, and the magnetization M16 spirals around the vortex core VC. Accordingly, while the magnetization M16 in the same direction as the magnetization M12 of the second magnetization free layer 12 is present in the first magnetization free layer 16, the magnetization M16 in a direction orthogonal to the direction of the magnetization M12 of the second magnetization free layer 12 and the magnetization M16 in a direction antiparallel to the direction of the magnetization M12 are also present in the first magnetization free layer 16. This causes the resistance value RC of the magnetoresistive effect element 10C to be relatively high. However, as illustrated in FIGS. 10(A), 10(B), 10(D), and 10(E), when subjected to the external magnetic field, the first magnetization free layer 16 having the spin-vortex structure will increase in magnetic moment in the same direction as the direction of the external magnetic field. In other words, most part of the first magnetization free layer 16 will have the magnetization M16 in the same direction as the direction of the external magnetic field. The direction of the magnetization M12 of the second magnetization free layer 12 also coincides with the direction of the external magnetic field. Accordingly, the magnetoresistive effect element 10C decreases in resistance value with increasing intensity of the external magnetic field applied to the magnetoresistive effect element 10C with a current fed therethrough in the z direction.

In this way, the magnetoresistive effect element 10C according to Modification Example 1-3 also exhibits a change in resistance value corresponding to the intensity (i.e., the magnetic flux density) of the external magnetic field applied to the magnetoresistive effect element 10C. Therefore, understanding a correlation between the intensity (i.e., the magnetic flux density) of the external magnetic field and the resistance value of the magnetoresistive effect element 10C in advance helps to calculate the intensity of the external magnetic field through detection of the change in the resistance value.

Further, as compared with the magnetoresistive effect element 10 of the foregoing first example embodiment, the magnetoresistive effect element 10C exhibits low variations in resistance value in response to a z-direction component of the external magnetic field. This helps to achieve higher reliability.

### Fourth Modification Example

FIG. 11 is a cross-sectional diagram illustrating a cross-sectional configuration example of a magnetoresistive effect element 10D according to a fourth modification example (hereinafter, “Modification Example 1-4”) of the first example embodiment of the disclosure. FIG. 11 corresponds to FIG. 1B illustrating the magnetoresistive effect element 10 according to the foregoing first example embodiment. The magnetoresistive effect element 10D according to Modification Example 1-4 may include a stacked structure S10D instead of the stacked structure S10. The magnetoresistive effect element 10D may be otherwise substantially the same in configuration as the magnetoresistive effect element 10 according to the foregoing first example embodiment. In the stacked structure S10D, the magnetization M11 of the first magnetization free layer 11 and the magnetization M12 of the second magnetization free layer 12 may be antiferromagnetically coupled to each other. When the nonmagnetic layer 13 is the tunnel barrier layer, the magnetization M11 and the magnetization M12 are magnetostatically coupled to each other and are antiparallel to each other. When the nonmagnetic layer 13 is the nonmagnetic electrically-conductive layer, the magnetization M11 and the magnetization M12 are coupled to each other by Ruderman-Kittel-Kasuya-Yosida (RKKY) interaction and are antiparallel to each other.

FIG. 12 is a characteristic diagram illustrating a relationship between the magnetic flux density B of an external magnetic field applied to the magnetoresistive effect element 10D and a resistance value RD of the magnetoresistive effect element 10D when a current is fed through the magnetoresistive effect element 10D in the z direction. In FIG. 12, the horizontal axis represents the magnetic flux density B, and the vertical axis represents the resistance value RD. FIG. 12 corresponds to FIG. 2 illustrating the characteristic diagram of the magnetoresistive effect element 10 of the foregoing first example embodiment.

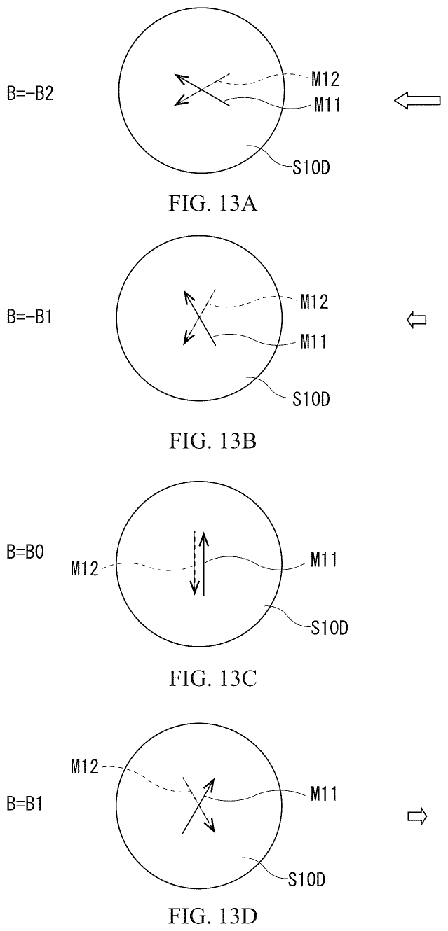

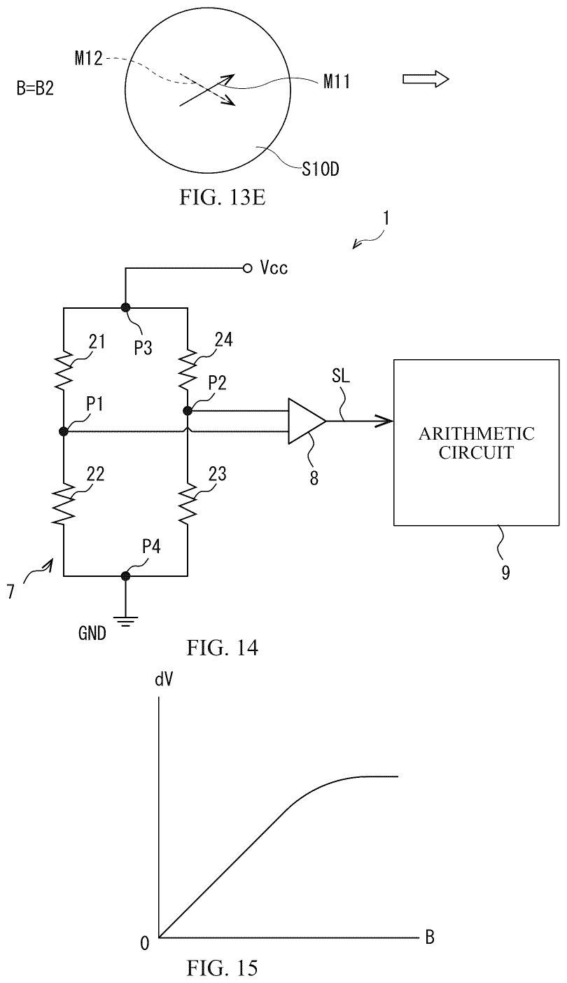

FIGS. 13A to 13E are planar diagrams schematically illustrating a behavior of each of the first magnetization free layer 11 and the second magnetization free layer 12 of the magnetoresistive effect element 10D when the external magnetic field is applied, in other words, how the magnetizations M11 and M12 each change in accordance with the magnitude of the magnetic flux density B of the external magnetic field applied to the magnetoresistive effect element 10D. FIG. 13A illustrates the directions of the magnetizations M11 and M12 when the magnetic flux density B is equal to −B2 in the characteristic diagram of FIG. 12. FIG. 13B illustrates the directions of the magnetizations M11 and M12 when the magnetic flux density B is equal to −B1 in the characteristic diagram of FIG. 12. FIG. 13C illustrates the directions of the magnetizations M11 and M12 when the magnetic flux density B is zero (0) in the characteristic diagram of FIG. 12. FIG. 13D illustrates the directions of the magnetizations M11 and M12 when the magnetic flux density B is equal to B1 in the characteristic diagram of FIG. 12. FIG. 13E illustrates the directions of the magnetizations M11 and M12 when the magnetic flux density B is equal to B2 in the characteristic diagram of FIG. 12. Note that B1 and −B1 are equal in absolute value, and B2 and −B2 are equal in absolute value. The length and the direction of the hollow arrow illustrated in each of FIGS. 13A, 13B, 13D, and 13E represent the intensity and the direction, respectively, of the external magnetic field applied to the magnetoresistive effect element 10D. For example, the hollow arrow having a greater length indicates that the external magnetic field has a greater intensity. Further, FIGS. 13A and 13B indicate that the external magnetic field is applied to the magnetoresistive effect element 10D in the leftward direction in the sheet plane, and FIGS. 13D and 13E indicate that the external magnetic field is applied to the magnetoresistive effect element 10D in the rightward direction in the sheet plane.

As illustrated in FIG. 12, the magnetoresistive effect element 10D exhibits a behavior similar to that of the magnetoresistive effect element 10 of the foregoing first example embodiment in response to the external magnetic field applied to the magnetoresistive effect element 10D. For example, the resistance value RD of the magnetoresistive effect element 10D reaches a maximum resistance value RDmax when the magnetic flux density B is zero. FIGS. 11 and 13C schematically illustrate a state of the magnetoresistive effect element 10D when the magnetic flux density B is zero. As indicated in FIGS. 11 and 13C, when the magnetic flux density B of the external magnetic field is zero, the respective directions of the magnetizations M11 and M12 are antiparallel to each other. This causes the resistance value RD of the magnetoresistive effect element 10D to be relatively high. However, as illustrated in FIGS. 13(A), 13(B), 13(D), and 13(E), when subjected to the external magnetic field, the respective directions of the magnetizations M11 and M12 rotate to approach the direction of the external magnetic field. Here, as the intensity, i.e., the absolute value of the magnetic flux density B, of the external magnetic field increases, the directions of the magnetizations M11 and M12 approach being parallel to each other. Accordingly, the magnetoresistive effect element 10D decreases in resistance value with increasing intensity of the external magnetic field applied to the magnetoresistive effect element 10D with a current fed therethrough in the z direction.

In this way, the magnetoresistive effect element 10D according to Modification Example 1-4 also exhibits a change in resistance value corresponding to the intensity (i.e., the magnetic flux density) of the external magnetic field applied to the magnetoresistive effect element 10D. Therefore, understanding a correlation between the intensity (i.e., the magnetic flux density) of the external magnetic field and the resistance value of the magnetoresistive effect element 10D in advance helps to calculate the intensity of the external magnetic field through detection of the change in the resistance value.

### 2. Second Example Embodiment

### [Configuration of Magnetic Field Detection Device 1]

Reference is now made to FIG. 14 to describe a configuration of a magnetic field detection device 1 according to a second example embodiment of the disclosure. FIG. 14 is a circuit diagram schematically illustrating a circuit configuration of the magnetic field detection device 1 according to the second example embodiment of the disclosure. As illustrated in FIG. 14, the magnetic field detection device 1 may include a bridge circuit 7, a difference detector 8, and an arithmetic circuit 9. The magnetic field detection device 1 may be configured to detect a change in intensity of an external magnetic field applied to the magnetic field detection device 1, based on a change in output from the bridge circuit 7.

The bridge circuit 7 may include four resistors 21 to 24. The bridge circuit 7 may have a configuration in which a pair of resistors 21 and 22 and a pair of resistors 23 and 24 are coupled in parallel to each other. The resistor 21 and the resistor 22 may be coupled in series to each other. The resistor 23 and the resistor 24 may be coupled in series to each other. For example, in the bridge circuit 7, a first end of the resistor 21 and a first end of the resistor 22 may be coupled to each other at a node P1, a first end of the resistor 23 and a first end of the resistor 24 may be coupled to each other at a node P2, a second end of the resistor 21 and a second end of the resistor 24 may be coupled to each other at a node P3, and a second end of the resistor 22 and a second end of the resistor 23 may be coupled to each other at a node P4. The node P3 may be set to a first potential, and the node P4 may be set to a second potential. In the example embodiment illustrated in FIG. 14, the node P3 may be coupled to a power supply Vcc, and the node P4 may be coupled to a ground terminal GND. The node P1 and the node P2 may be coupled to respective input-side terminals of the difference detector 8, for example.

In the bridge circuit 7, the magnetoresistive effect element 10 described in relation to the foregoing first example embodiment may be employed as each of the resistors 21 and 23. For example, the resistors 21 and 23 may each be configured to detect the intensity of the external magnetic field as a target of detection. In some embodiments, any of the magnetoresistive effect elements 10A to 10D according to Modification Examples 1-1 to 1-4 described above may be employed as each of the resistors 21 and 23. In the bridge circuit 7, in contrast, the resistors 22 and 24 may each be a fixed resistor, for example. Note that the resistors 22 and 24 are each not limited to the fixed resistor. In some embodiments where each of the resistors 22 and 24 is a magnetoresistive effect element, a magnetization direction of the magnetization pinned layer of the magnetoresistive effect element serving as the resistor 22 and a magnetization direction of the magnetization pinned layer of the magnetoresistive effect element serving as the resistor 24 may be opposite to each other. One reason for this is that in such a case, a resistance variation of the resistor 22 exhibited in accordance with the angle of the external magnetic field and a resistance variation of the resistor 24 exhibited in accordance with the angle of the external magnetic field are allowed to be in opposite directions to each other, that is, to be of opposite signs, which helps to allow the respective resistance variations to cancel each other out by taking a differential potential between a resistance of the resistor 22 and a resistance of the resistor 24, which in turn helps to offer expectations for relatively easy detection of the intensity of the external magnetic field.

### [Operation of Magnetic Field Detection Device 1]

In the magnetic field detection device 1, signals taken out from the nodes P1 and P2 of the bridge circuit 7 may flow into the difference detector 8. The difference detector 8 may detect a potential difference between the nodes P1 and P2 occurring when a voltage is applied between the nodes P3 and P4, that is, a differential output dV that is a difference between a voltage drop occurring in the resistor 21 and a voltage drop occurring in the resistor 24, and may output the detected differential output dV as a difference signal SL to the arithmetic circuit 9. In the magnetic field detection device 1, when the resistors 22 and 24 are each configured to have a resistance value equal to the resistance value of each of the resistors 22 and 24 at a zero magnetic field, the differential output dV is zero (0) in an initial state where no external magnetic field is applied. In a state where an external magnetic field is applied to the bridge circuit 7, the magnetoresistive effect elements 10 serving as the resistors 21 and 23 each exhibit a change in resistance value corresponding to the intensity of the applied external magnetic field. This results in the differential output dV corresponding to the intensity of the external magnetic field.

FIG. 15 is a characteristic diagram schematically illustrating a relationship between the magnetic flux density B (on the horizontal axis) and the differential output dV (on the vertical axis). The magnetic flux density B indicates the intensity of the external magnetic field. As indicated in FIG. 15, the magnetic field detection device 1 allows the magnetic flux density B and the differential output dV to have a proportional relationship within a range of the magnetic flux density B not greater than a certain magnitude. In accordance with a correlation illustrated in FIG. 15, the arithmetic circuit 9 may calculate the intensity of the external magnetic field applied to the bridge circuit 7, based on the difference signal SL from the difference detector 8.

In this way, the magnetic field detection device 1 helps to determine the intensity of the applied external magnetic field.

### 3. Third Example Embodiment

### [Configuration of Magnetic Field Detection Device 2]

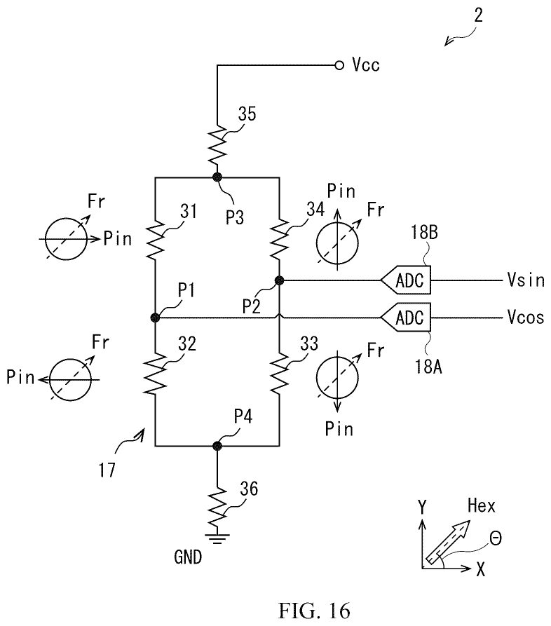

Reference is now made to FIG. 16 to describe a configuration of a magnetic field detection device 2 according to a third example embodiment of the disclosure. FIG. 16 is a circuit diagram schematically illustrating a circuit configuration of the magnetic field detection device 2 according to the third example embodiment of the disclosure. As illustrated in FIG. 16, the magnetic field detection device 2 may include resistors 35 and 36, a bridge circuit 17, and analog-to-digital converter circuits (ADCs) 18A and 18B. The magnetic field detection device 2 may be configured to detect a change in intensity of an external magnetic field applied to the magnetic field detection device 2, based on changes in outputs from the resistors 35 and 36 and the bridge circuit 17.

The bridge circuit 17 may include resistors 31 to 34. The bridge circuit 17 may have a configuration in which a pair of resistors 31 and 32 and a pair of resistors 33 and 34 are coupled in parallel to each other. The resistor 31 and the resistor 32 may be coupled in series to each other. The resistor 33 and the resistor 34 may be coupled in series to each other. For example, in the bridge circuit 17, a first end of the resistor 31 and a first end of the resistor 32 may be coupled to each other at the node P1, a first end of the resistor 33 and a first end of the resistor 34 may be coupled to each other at the node P2, a second end of the resistor 31 and a second end of the resistor 34 may be coupled to each other at the node P3, and a second end of the resistor 32 and a second end of the resistor 33 may be coupled to each other at the node P4. In the example embodiment illustrated in FIG. 16, the node P3 may be coupled to the power supply Vcc via the resistor 35, and the node P4 may be coupled to the ground terminal GND via the resistor 36. The node P1 may be coupled to an input terminal of the ADC 18A, and the node P2 may be coupled to an input terminal of the ADC 18B. The resistors 31 to 34 of the bridge circuit 17 may each be a GMR element having a spin-valve structure, for example. For example, the resistors 31 to 34 may each include a stacked structure including a magnetization free layer, a nonmagnetic layer, and a magnetization pinned layer, and may exhibit a resistance value that changes in accordance with the direction of the external magnetic field. The magnetization free layer has a magnetization that changes direction in accordance with the direction of the external magnetic field. The magnetization pinned layer has a magnetization that is pinned in a specific direction irrespective of the external magnetic field.

The bridge circuit 17 may correspond to a specific but non-limiting example of a “bridge circuit” in one embodiment of the disclosure. The node P3 may correspond to a specific but non-limiting example of a “first terminal” in one embodiment of the disclosure. The node P4 may correspond to a specific but non-limiting example of a “second terminal” in one embodiment of the disclosure. A “first potential” in one embodiment of the disclosure may correspond to a power supply potential set by the power supply Vcc. A “second potential” in one embodiment of the disclosure may correspond to a ground potential. The resistor 31 may correspond to a specific but non-limiting example of a “first magnetoresistive effect element” in one embodiment of the disclosure. The resistor 32 may correspond to a specific but non-limiting example of a “second magnetoresistive effect element” in one embodiment of the disclosure.

In the magnetic field detection device 2, the magnetoresistive effect element 10 described in relation to the foregoing first example embodiment may be employed as each of the resistors 35 and 36. For example, the resistors 35 and 36 may each be configured to detect the intensity of the external magnetic field as a target of detection. In some embodiments, any of the magnetoresistive effect elements 10A, 10C, and 10D according to Modification Examples 1-1, 1-3, and 1-4 described above may be employed as each of the resistors 35 and 36.

In the magnetic field detection device 2, the bridge circuit 17 may serve as the magnetic field angle data detector to detect the direction of the external magnetic field, and the resistors 35 and 36 may serve as the magnetic field intensity data detector to detect the intensity of the external magnetic field. Note that a signal component including magnetic field angle data and a signal component including magnetic field intensity data may be outputted as paired digital signals corresponding to analog signals that are taken out from the respective nodes P1 and P2 and converted at the respective ADCs 18A and 18B.

FIG. 16 schematically illustrates a magnetization direction Fr of the magnetization free layer and a magnetization direction Pin of the magnetization pinned layer when each of the resistors 31 to 34 is a magnetoresistive effect element. In FIG. 16, the magnetization direction Fr is indicated in a dashed arrow, and the magnetization direction Pin is indicated in a solid arrow. Note that in FIG. 16, an X-axis direction and a Y-axis direction are assumed to be parallel to a plane orthogonal to the z direction, and an external magnetic field Hex is assumed to be applied in a direction at an angle Θ with respect to a +X direction. In an example of the bridge circuit 17 illustrated in FIG. 16, the magnetization direction Pin of the magnetization pinned layer of the resistor 31 may be pinned in the +X direction, the magnetization direction Pin of the magnetization pinned layer of the resistor 32 may be pinned in a −X direction, the magnetization direction Pin of the magnetization pinned layer of the resistor 33 may be pinned in a −Y direction, and the magnetization direction Pin of the magnetization pinned layer of the resistor 34 may be pinned in a +Y direction. In this case, where an output from the ADC 18A is represented by V cos and an output from the ADC 18B is represented by V sin, an intensity Vamp of the external magnetic field Hex is calculated by Equation (1) below, and the angle Θ of the external magnetic field Hex is calculated by Equation (2) below. Note that in Equations (1) and (2), Vs0 represents the output V sin when the angle Θ is 0°, and Vc0 represents the output V cos when the angle Θ is 90°.

$${V}_{a m p} = {( {( {V}_{sin} - {V}_{s 0} )}^{2} + {( {V}_{c o s} - {V}_{c 0} )}^{2} )}^{\frac{1}{2}} \qquad ( 1 )$$

$$Θ = atan ( \frac{{V}_{sin} - {V}_{s 0}}{{V}_{c o s} - {V}_{c 0}} ) \qquad ( 2 )$$

In this way, in the magnetic field detection device 2, the bridge circuit 17 serving as the magnetic field angle data detector to detect the direction of the external magnetic field and the resistors 35 and 36 serving as the magnetic field intensity data detector to detect the intensity of the external magnetic field may be integrated into a single circuit. This helps to achieve simplification and size reduction of an overall configuration.

### 4. Fourth Example Embodiment

### [Configuration of Magnetic Field Detection Device 3]

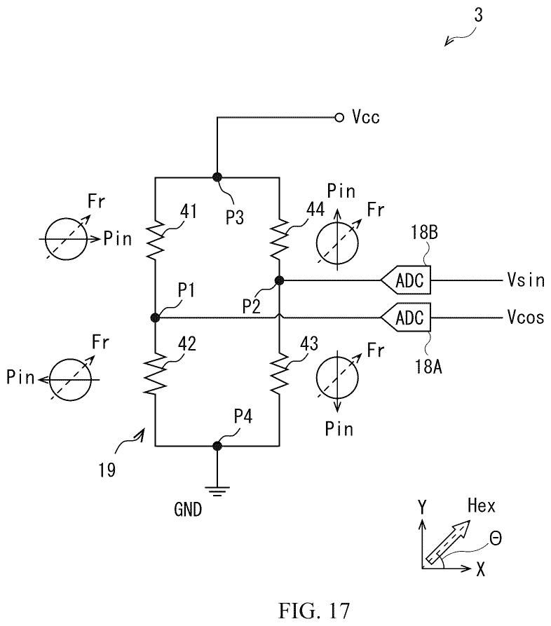

Reference is now made to FIG. 17 to describe a configuration of a magnetic field detection device 3 according to a fourth example embodiment of the disclosure. FIG. 17 is a circuit diagram schematically illustrating a circuit configuration of the magnetic field detection device 3 according to the fourth example embodiment of the disclosure. As illustrated in FIG. 17, the magnetic field detection device 3 may include neither of the resistors 35 and 36, and may include a bridge circuit 19 instead of the bridge circuit 17. The magnetic field detection device 3 may be otherwise substantially the same in configuration as the magnetic field detection device 2. The magnetic field detection device 3 may be configured to detect a change in intensity of an external magnetic field applied to the magnetic field detection device 3, based on a change in output from the bridge circuit 19.

The bridge circuit 19 may include resistors 41 to 44. The bridge circuit 19 may have a configuration in which a pair of resistors 41 and 42 and a pair of resistors 43 and 44 are coupled in parallel to each other. The resistor 41 and the resistor 42 may be coupled in series to each other. The resistor 43 and the resistor 44 may be coupled in series to each other. For example, in the bridge circuit 19, a first end of the resistor 41 and a first end of the resistor 42 may be coupled to each other at the node P1, a first end of the resistor 43 and a first end of the resistor 44 may be coupled to each other at the node P2, a second end of the resistor 41 and a second end of the resistor 44 may be coupled to each other at the node P3, and a second end of the resistor 42 and a second end of the resistor 43 may be coupled to each other at the node P4. In the example embodiment illustrated in FIG. 17, the node P3 may be coupled to the power supply Vcc, and the node P4 may be coupled to the ground terminal GND. The node P1 may be coupled to the input terminal of the ADC 18A, and the node P2 may be coupled to the input terminal of the ADC 18B. The resistors 41 to 44 of the bridge circuit 19 may be the magnetoresistive effect element 10B according to Modification Example 1-2 described above, for example.

The bridge circuit 19 may correspond to a specific but non-limiting example of the “bridge circuit” in one embodiment of the disclosure. The node P3 may correspond to a specific but non-limiting example of the “first terminal” in one embodiment of the disclosure. The node P4 may correspond to a specific but non-limiting example of the “second terminal” in one embodiment of the disclosure. The “first potential” in one embodiment of the disclosure may correspond to the power supply potential set by the power supply Vcc. The “second potential” in one embodiment of the disclosure may correspond to the ground potential. The resistor 41 may correspond to a specific but non-limiting example of the “first magnetoresistive effect element” in one embodiment of the disclosure. The resistor 42 may correspond to a specific but non-limiting example of the “second magnetoresistive effect element” in one embodiment of the disclosure.

In the magnetic field detection device 3, the bridge circuit 19 may serve as the magnetic field angle data detector to detect the direction of the external magnetic field and also as the magnetic field intensity data detector to detect the intensity of the external magnetic field. In the magnetic field detection device 3, the intensity Vamp of the external magnetic field Hex is calculated by Equation (1), and the angle Θ of the external magnetic field Hex is calculated by Equation (2), as in the magnetic field detection device 2 according to the foregoing third example embodiment.

In this way, the magnetic field detection device 3 may include the bridge circuit 19 serving as both the magnetic field angle data detector to detect the direction of the external magnetic field and the magnetic field intensity data detector to detect the intensity of the external magnetic field. This helps to achieve simplification and size reduction of the overall configuration.

### 5. Fifth Example Embodiment

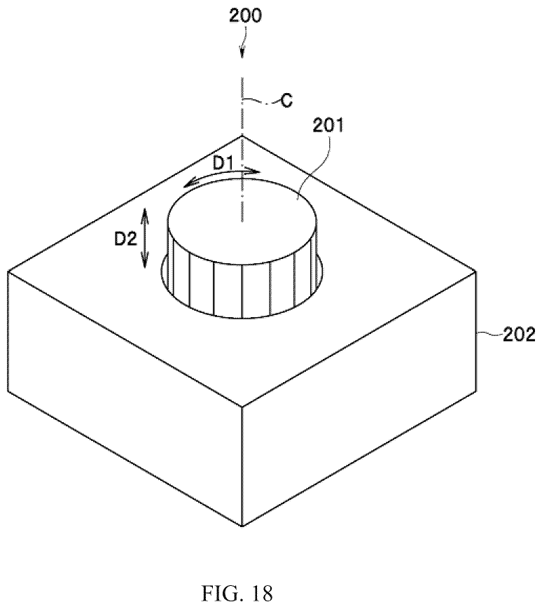

Reference is now made to FIG. 18 to describe a magnetic sensor system 200 according to a fifth example embodiment of the disclosure. FIG. 18 is a perspective diagram illustrating an overall configuration example of the magnetic sensor system 200 according to the fifth example embodiment. The magnetic sensor system 200 may correspond to a specific but non-limiting example of a “magnetic sensor system” in one embodiment of the disclosure.

The magnetic sensor system 200 may include a component 201, and a body 202 accommodating all or a part of the component 201. The component 201 may incorporate a magnetic field generator generating a magnetic field, such as a permanent magnet or an electromagnet, and may be configured to perform an action of rotating in a direction D1 around a reference axis C as a first axis and an action of moving in a direction D2 parallel to the reference axis C. The component 201 may be a component to be caused to operate by human operation, such as a knob. Non-limiting examples of the magnetic sensor system 200 including such a component 201 may include an operation device for a car air-conditioner, a car navigation system, or any of other in-vehicle devices, an operation device for a digital camera, a radio, or any of other portable electronic devices, and a crown of a smartwatch or any of other electronic watches serving as wearable electronic devices. In some embodiments, the component 201 may operate in synchronization with any driving device. In some embodiments, the body 202 may incorporate a magnetic field detection device. Any of the magnetic field detection devices 1 to 3 described in relation to the foregoing second to fourth example embodiments, respectively, may be used as the magnetic field detection device incorporated in the body 202.

For example, the magnetic sensor system 200 is configured to change the direction of the magnetic field applied to the magnetic field detection device, by causing the magnetic field detection device and the magnetic field generator to rotate relative to each other around the reference axis C as a center of rotation, and configured to change the intensity of the magnetic field applied to the magnetic field detection device, by changing relative positions of the magnetic field detection device and the magnetic field generator along the reference axis C.

In this way, the magnetic sensor system 200 helps to detect both the angle and the intensity of the magnetic field applied to the magnetic field detection device, while being simple in configuration.

The example embodiments and modification examples described above are to facilitate understanding of the disclosure, and are not intended to limit the disclosure. Each element disclosed in the example embodiments and modification examples described above shall thus be construed to include all design modifications and equivalents that fall within the technical scope of the disclosure. In other words, the disclosure is not limited to the example embodiments and modification examples described above, and may be modified in a variety of ways.

The disclosure encompasses any possible combination of some or all of the various embodiments and the modification examples described herein and incorporated herein. It is possible to achieve at least the following configurations from the foregoing example embodiments and modification examples of the disclosure.

(1)

A magnetoresistive effect element including
a stacked structure including a first magnetization free layer, a first nonmagnetic layer, and a second magnetization free layer that are stacked in order in a stacking direction, in which
an outer edge of the stacked structure along a plane orthogonal to the stacking direction has an isotropic shape.
   (2)

The magnetoresistive effect element according to (1), in which
the first magnetization free layer has an easy axis of magnetization along the stacking direction, and
the second magnetization free layer has a hard axis of magnetization along the stacking direction.
   (3)

The magnetoresistive effect element according to (1), in which the first magnetization free layer and the second magnetization free layer each have an easy axis of magnetization along the stacking direction.

(4)

The magnetoresistive effect element according to (1), in which the stacked structure further includes a second nonmagnetic layer and a magnetization pinned layer that are stacked in order on a side, of the second magnetization free layer, opposite to the first nonmagnetic layer.

(5)

The magnetoresistive effect element according to (1), in which
the first magnetization free layer has a spin-vortex structure including a magnetization that spirals along the plane, and
the second magnetization free layer has a hard axis of magnetization along the stacking direction.
   (6)

The magnetoresistive effect element according to (1), in which the first magnetization free layer and the second magnetization free layer are antiferromagnetically coupled to each other.

(7)

The magnetoresistive effect element according to (6), in which an angle between a magnetization direction of the first magnetization free layer and a magnetization direction of the second magnetization free layer in a state where no external magnetic field is applied is greater than 90 degrees and less than or equal to 180 degrees.

(8)

The magnetoresistive effect element according to (1), in which the outer edge of the stacked structure has a circular shape.

(9)

The magnetoresistive effect element according to (1), in which an anisotropic magnetic field intensity of the first magnetization free layer and an anisotropic magnetic field intensity of the second magnetization free layer are different from each other.

(10)

A magnetic field detection device including
one or more magnetoresistive effect elements, in which
the one or more magnetoresistive effect elements each include a stacked structure including a first magnetization free layer, a first nonmagnetic layer, and a second magnetization free layer that are stacked in order in a stacking direction, and
an outer edge of the stacked structure along a plane orthogonal to the stacking direction has an isotropic shape.
   (11)

The magnetic field detection device according to (10), further including an angle sensor coupled in series to the one or more magnetoresistive effect elements.

(12)

The magnetic field detection device according to (10), further including:
a first terminal to be set to a first potential;
a second terminal to be set to a second potential different from the first potential; and
a bridge circuit disposed between the first terminal and the second terminal, in which
the one or more magnetoresistive effect elements include a first magnetoresistive effect element and a second magnetoresistive effect element, and
the bridge circuit includes the first magnetoresistive effect element and the second magnetoresistive effect element.
   (13)

The magnetic field detection device according to (12), in which the bridge circuit includes a first fixed resistor and a second fixed resistor in addition to the first magnetoresistive effect element and the second magnetoresistive effect element.

(14)

The magnetic field detection device according to (12), in which
the bridge circuit includes a third magnetoresistive effect element and a fourth magnetoresistive effect element in addition to the first magnetoresistive effect element and the second magnetoresistive effect element,
the third magnetoresistive effect element and the fourth magnetoresistive effect element each include a magnetization pinned layer, and
a magnetization direction of the magnetization pinned layer of the third magnetoresistive effect element and a magnetization direction of the magnetization pinned layer of the fourth magnetoresistive effect element are opposite to each other.
   (15)

The magnetic field detection device according to (10), further including:
a first terminal to be set to a first potential;
a second terminal to be set to a second potential different from the first potential; and
a bridge circuit disposed between the first terminal and the second terminal, in which
the one or more magnetoresistive effect elements are
   disposed between the first terminal and the bridge circuit, or between the second terminal and the bridge circuit, or
   disposed between the first terminal and the bridge circuit, and between the second terminal and the bridge circuit.
      (16)

The magnetic field detection device according to (15), in which the bridge circuit is configured to detect both an intensity of an external magnetic field applied to the bridge circuit and an angle of the external magnetic field.

(17)

The magnetic field detection device according to (10), in which the outer edge of the stacked structure has a circular shape.

(18)

A magnetic field detection device including
a bridge circuit including first to fourth magnetoresistive effect elements, in which
the first to fourth magnetoresistive effect elements each include a stacked structure including a magnetization pinned layer, a second nonmagnetic layer, a second magnetization free layer, a first nonmagnetic layer, and a first magnetization free layer that are stacked in order in a stacking direction,
the first magnetization free layer has an easy axis of magnetization along the stacking direction, and
the second magnetization free layer has a hard axis of magnetization along the stacking direction.
   (19)

The magnetic field detection device according to (18), in which an outer edge of the stacked structure along a plane orthogonal to the stacking direction has an isotropic shape.

(20)

The magnetic field detection device according to (18) or (19), in which the bridge circuit is configured to detect both an intensity of an external magnetic field applied to the bridge circuit and an angle of the external magnetic field.

(21)

A magnetic sensor system including:
a magnetic field detection device; and
a magnetic field generator generating a magnetic field,
the magnetic sensor system being configured to change a direction of the magnetic field applied to the magnetic field detection device, by causing the magnetic field detection device and the magnetic field generator to rotate relative to each other around a first axis as a center of rotation, and configured to change an intensity of the magnetic field applied to the magnetic field detection device, by changing relative positions of the magnetic field detection device and the magnetic field generator along the first axis, in which
the magnetic field detection device includes one or more magnetoresistive effect elements,
the one or more magnetoresistive effect elements each include a stacked structure including a first magnetization free layer, a first nonmagnetic layer, and a second magnetization free layer that are stacked in order in a stacking direction, and
an outer edge of the stacked structure along a plane orthogonal to the stacking direction has an isotropic shape.

A magnetoresistive effect element according to at least one embodiment of the disclosure exhibits a resistance value corresponding to an intensity of an in-plane component, of an external magnetic field, along a plane orthogonal to a stacking direction. The resistance value of the magnetoresistive effect element changes in response to a change in intensity of the in-plane component of the external magnetic field, and does not depend on a direction of the in-plane component of the external magnetic field. In other words, the resistance value of the magnetoresistive effect element isotropically changes in response to the change in intensity of the in-plane component of the external magnetic field, irrespective of the direction of the in-plane component of the external magnetic field.

A magnetic field detection device and a magnetic sensor system according to at least one embodiment of the disclosure, and the magnetoresistive effect element according to at least one embodiment of the disclosure for use in the magnetic field detection device or the magnetic sensor system are each simple in configuration and yet make it possible to isotropically detect the intensity of an external magnetic field without dependence on the direction of the external magnetic field.

It is to be noted that the effects of the disclosure should not be limited thereto, and may be any of the effects described herein.

Although the disclosure has been described hereinabove in terms of the example embodiment and modification examples, the disclosure is not limited thereto. It should be appreciated that variations may be made in the described example embodiment and modification examples by those skilled in the art without departing from the scope of the disclosure as defined by the following claims.

The limitations in the claims are to be interpreted broadly based on the language employed in the claims and not limited to examples described in this specification or during the prosecution of the application, and the examples are to be construed as non-exclusive.

As used in this specification and the appended claims, the singular forms “a,” “an,” and “the” include, especially in the context of the claims, are to be construed to cover both the singular and the plural, unless otherwise indicated herein or clearly contradicted by context.

Throughout this specification and the appended claims, unless the context requires otherwise, the terms “comprise”, “include”, “have”, and their variations are to be construed to cover the inclusion of a stated element, integer or step but not the exclusion of any other non-stated element, integer or step.

The use of the terms first, second, etc. do not denote any order or importance, but rather the terms first, second, etc. are used to distinguish one element from another.

The term “substantially”, “approximately”, “about”, and its variants having the similar meaning thereto are defined as being largely but not necessarily wholly what is specified as understood by one of ordinary skill in the art.

The term “disposed on/provided on/formed on” and its variants having the similar meaning thereto as used herein refer to elements disposed directly in contact with each other or indirectly by having intervening structures therebetween.

What is claimed is:

1. A magnetoresistive effect element comprising
a stacked structure including a first magnetization free layer, a first nonmagnetic layer, and a second magnetization free layer that are stacked in order in a stacking direction, wherein
an outer edge of the stacked structure along a plane orthogonal to the stacking direction has an isotropic shape.

2. The magnetoresistive effect element according to claim 1, wherein
the first magnetization free layer has an easy axis of magnetization along the stacking direction, and
the second magnetization free layer has a hard axis of magnetization along the stacking direction.

3. The magnetoresistive effect element according to claim 1, wherein the first magnetization free layer and the second magnetization free layer each have an easy axis of magnetization along the stacking direction.

4. The magnetoresistive effect element according to claim 1, wherein the stacked structure further includes a second nonmagnetic layer and a magnetization pinned layer that are stacked in order on a side, of the second magnetization free layer, opposite to the first nonmagnetic layer.

5. The magnetoresistive effect element according to claim 1, wherein
the first magnetization free layer has a spin-vortex structure including a magnetization that spirals along the plane, and
the second magnetization free layer has a hard axis of magnetization along the stacking direction.

6. The magnetoresistive effect element according to claim 1, wherein the first magnetization free layer and the second magnetization free layer are antiferromagnetically coupled to each other.

7. The magnetoresistive effect element according to claim 6, wherein an angle between a magnetization direction of the first magnetization free layer and a magnetization direction of the second magnetization free layer in a state where no external magnetic field is applied is greater than 90 degrees and less than or equal to 180 degrees.

8. The magnetoresistive effect element according to claim 1, wherein the outer edge of the stacked structure has a circular shape.

9. The magnetoresistive effect element according to claim 1, wherein an anisotropic magnetic field intensity of the first magnetization free layer and an anisotropic magnetic field intensity of the second magnetization free layer are different from each other.

10. A magnetic field detection device comprising
one or more magnetoresistive effect elements, wherein
the one or more magnetoresistive effect elements each include a stacked structure including a first magnetization free layer, a first nonmagnetic layer, and a second magnetization free layer that are stacked in order in a stacking direction, and
an outer edge of the stacked structure along a plane orthogonal to the stacking direction has an isotropic shape.

11. The magnetic field detection device according to claim 10, further comprising an angle sensor coupled in series to the one or more magnetoresistive effect elements.

12. The magnetic field detection device according to claim 10, further comprising:
a first terminal to be set to a first potential;
a second terminal to be set to a second potential different from the first potential; and
a bridge circuit disposed between the first terminal and the second terminal, wherein
the one or more magnetoresistive effect elements include a first magnetoresistive effect element and a second magnetoresistive effect element, and
the bridge circuit includes the first magnetoresistive effect element and the second magnetoresistive effect element.

13. The magnetic field detection device according to claim 12, wherein the bridge circuit includes a first fixed resistor and a second fixed resistor in addition to the first magnetoresistive effect element and the second magnetoresistive effect element.

14. The magnetic field detection device according to claim 12, wherein
the bridge circuit includes a third magnetoresistive effect element and a fourth magnetoresistive effect element in addition to the first magnetoresistive effect element and the second magnetoresistive effect element,
the third magnetoresistive effect element and the fourth magnetoresistive effect element each include a magnetization pinned layer, and
a magnetization direction of the magnetization pinned layer of the third magnetoresistive effect element and a magnetization direction of the magnetization pinned layer of the fourth magnetoresistive effect element are opposite to each other.

15. The magnetic field detection device according to claim 10, further comprising:
a first terminal to be set to a first potential;
a second terminal to be set to a second potential different from the first potential; and
a bridge circuit disposed between the first terminal and the second terminal, wherein
the one or more magnetoresistive effect elements are
disposed between the first terminal and the bridge circuit, or between the second terminal and the bridge circuit, or
disposed between the first terminal and the bridge circuit, and between the second terminal and the bridge circuit.

16. The magnetic field detection device according to claim 15, wherein the bridge circuit is configured to detect both an intensity of an external magnetic field applied to the bridge circuit and an angle of the external magnetic field.

17. The magnetic field detection device according to claim 10, wherein the outer edge of the stacked structure has a circular shape.

18. A magnetic field detection device comprising
a bridge circuit including first to fourth magnetoresistive effect elements, wherein
the first to fourth magnetoresistive effect elements each include a stacked structure including a magnetization pinned layer, a second nonmagnetic layer, a second magnetization free layer, a first nonmagnetic layer, and a first magnetization free layer that are stacked in order in a stacking direction,
the first magnetization free layer has an easy axis of magnetization along the stacking direction, and
the second magnetization free layer has a hard axis of magnetization along the stacking direction.

19. The magnetic field detection device according to claim 18, wherein an outer edge of the stacked structure along a plane orthogonal to the stacking direction has an isotropic shape.

20. The magnetic field detection device according to claim 18, wherein the bridge circuit is configured to detect both an intensity of an external magnetic field applied to the bridge circuit and an angle of the external magnetic field.

21. A magnetic sensor system comprising:
a magnetic field detection device; and
a magnetic field generator generating a magnetic field,
the magnetic sensor system being configured to change a direction of the magnetic field applied to the magnetic field detection device, by causing the magnetic field detection device and the magnetic field generator to rotate relative to each other around a first axis as a center of rotation, and configured to change an intensity of the magnetic field applied to the magnetic field detection device, by changing relative positions of the magnetic field detection device and the magnetic field generator along the first axis, wherein
the magnetic field detection device includes one or more magnetoresistive effect elements,
the one or more magnetoresistive effect elements each include a stacked structure including a first magnetization free layer, a first nonmagnetic layer, and a second magnetization free layer that are stacked in order in a stacking direction, and
an outer edge of the stacked structure along a plane orthogonal to the stacking direction has an isotropic shape.
